(19) United States
(12) Patent Application Publication
(10) Pub. No.: US 2004/0009665 A1
(43) Pub. Date: Jan. 15, 2004

(54) Deposition of copper films

(75) Inventors: Ling Chen, Sunnyvale, CA (US); John A.T. Norman, Encinitas, CA (US); Mei Chang, Saratoga, CA (US)

Correspondence Address: Patent Counsel, Applied Materials, Inc., P.O. Box 450A, Santa Clara, CA, 95052, US

(73) Assignee: APPLIED MATERIALS, INC.

(21) Appl. No.: 10/441,242

(22) Filed: May 19, 2003

Related U.S. Application Data
(60) Provisional application No. 60/385,715, filed on Jun. 4, 2002.

(51) Int. Cl. C23C 16/18; H01L 21/44

(52) U.S. Cl. 438/687; 427/250; 427/252

(57) ABSTRACT

A method of forming a copper film on a substrate is described. The copper film is formed using a cyclical deposition technique by alternately adsorbing a copper-containing precursor and a reducing gas on a substrate. The copper film formation is compatible with integrated circuit fabrication processes. In one integrated circuit fabrication process, the copper film may be used as interconnect metallization.

### CROSS-REFERENCE TO RELATED APPLICATION

This application claims benefit of U.S. Provisional Application No. 60/385,715, filed Jun. 4, 2002, which is incorporated herein by reference in its entirety.

### BACKGROUND OF THE INVENTION

1. Field of the Invention

Embodiments of the present invention generally relate to a method of copper film deposition and, more particularly to a method of copper film deposition using cyclical deposition techniques.

2. Description of the Related Art

Sub-quarter micron, multi-level metallization is one of the key technologies for the next generation of very large scale integration (VLSI) and ultra large scale integration (ULSI) semiconductor devices. The multilevel interconnects that lie at the heart of this technology require the filling of contacts, vias, lines, and other features formed in high aspect ratio apertures. Reliable formation of these features is very important to the success of both VLSI and ULSI as well as to the continued effort to increase circuit density and quality on individual substrates and die.

As circuit densities increase, the widths of contacts, vias, lines and other features, as well as the dielectric materials between them may decrease to less than about 250 nm (nanometers), whereas the thickness of the dielectric layers remains substantially constant, with the result that the aspect ratios for the features, i.e., their height divided by width, increases. Many conventional deposition processes have difficulty filling structures where the aspect ratio exceeds 4:1, and particularly where the aspect ratio exceeds 10:1. As such, there is a great amount of ongoing effort being directed at the formation of void-free, nanometer-sized structures having aspect ratios wherein the ratio of feature height to feature width can be 8:1 or higher.

Additionally, as the feature widths decrease, the device current typically remains constant or increases, which results in an increased current density for such feature. Elemental aluminum (Al) and its alloys have been the traditional metals used to form vias and lines in semiconductor devices because of aluminum's perceived low electrical resistivity, its superior adhesion to most dielectric materials, its ease of patterning, and the ability to obtain it in a highly pure form. However, aluminum has a higher electrical resistivity than other more conductive metals such as copper (Cu), and aluminum also can suffer from electromigration leading to the formation of voids in the conductor.

Copper (Cu) and its alloys have lower resistivities than aluminum as well as a significantly higher electromigration resistance compared to aluminum. These characteristics are important for supporting the higher current densities experienced at high levels of integration and increased device speed. Copper also has good thermal conductivity. Therefore, copper is becoming a choice metal for filling sub-quarter micron, high aspect ratio interconnect features on semiconductor substrates.

Despite the desirability of using copper for semiconductor device fabrication, choices of fabrication methods for depositing copper into high aspect ratio features greater than 8:1 are limited. FIGS. 1A-1B illustrate the possible consequences of material layer deposition in a high aspect ratio feature 6 on a substrate 1. The high aspect ratio feature 6 may be any opening such as a space formed between adjacent dielectric material layers 2, such as a contact, via or trench. As shown in FIG. 1A, a copper layer 11 that is formed using conventional deposition techniques (e.g., chemical vapor deposition (CVD), physical vapor deposition (PVD) and electroplating) tends to be deposited on the top edges 6T of the feature 6 at a higher rate than at the bottom 6B or sides 6S thereof, creating an overhang. This overhang or excess deposition of material is sometimes referred to as crowning. Such excess material continues to build up on the top edges 6T of the feature 6, until the opening is closed off by the deposited copper layer 11, forming a void 14 therein. Additionally, as shown in FIG. 1B, a seam 8 may be formed when the copper layer 11 deposited on both sides 6S of the feature 6 opening merges. The presence of either voids or seams may result in unreliable integrated circuit performance.

Thus, there is a need for a method of copper deposition into high aspect ratio structures that provide void-free and seam-free fill thereof.

### SUMMARY OF THE INVENTION

A method of forming a copper film on a substrate is described. The copper film is formed using a cyclical deposition technique by alternately adsorbing a copper-containing precursor and a reducing gas on a substrate.

The copper film formation is compatible with integrated circuit fabrication processes. In one integrated circuit fabrication process, the copper film may be used as interconnect metallization. For an interconnect metallization process, a preferred process sequence includes providing a substrate having an interconnect pattern defined in one or more dielectric layers formed thereon. The interconnect pattern includes a barrier layer conformably deposited thereon. The interconnect pattern is filled with copper (Cu) metallization using a cyclical deposition technique by alternately adsorbing a copper-containing precursor and a reducing gas on the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1A-1B are cross-sectional views of possible deposition results for high aspect ratio features filled using conventional prior art deposition processes;

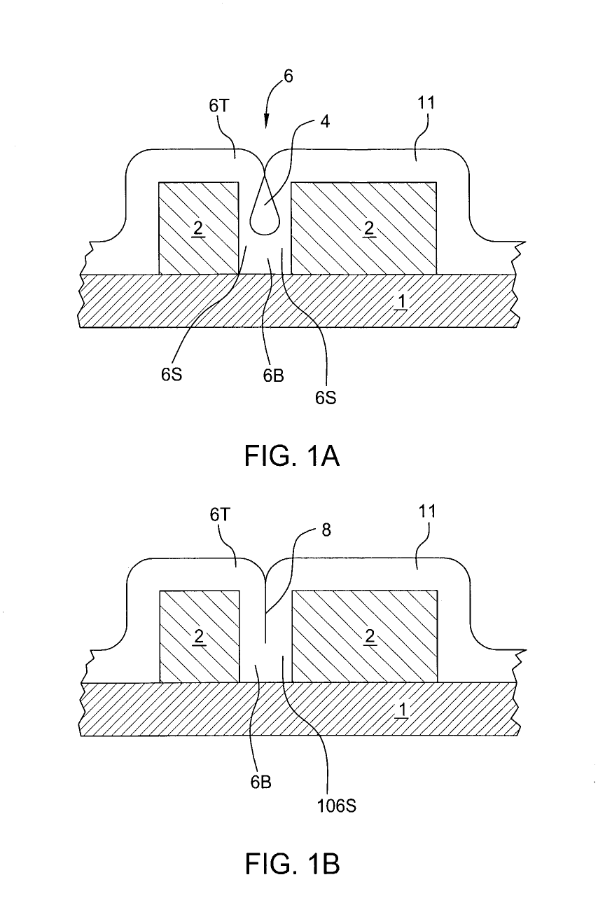

FIG. 2 depicts a schematic cross-sectional view of a process chamber that can be used for the practice of embodiments described herein;

FIG. 3 illustrates a process sequence for the formation of a copper film using cyclical deposition techniques according to one embodiment described herein;

FIG. 4 illustrates a process sequence for the formation of a copper film using cyclical deposition techniques according to an alternate embodiment described herein; and

FIGS. 5A-5B illustrate schematic cross-sectional views of an integrated circuit at different stages of an interconnect fabrication sequence.

### DETAILED DESCRIPTION

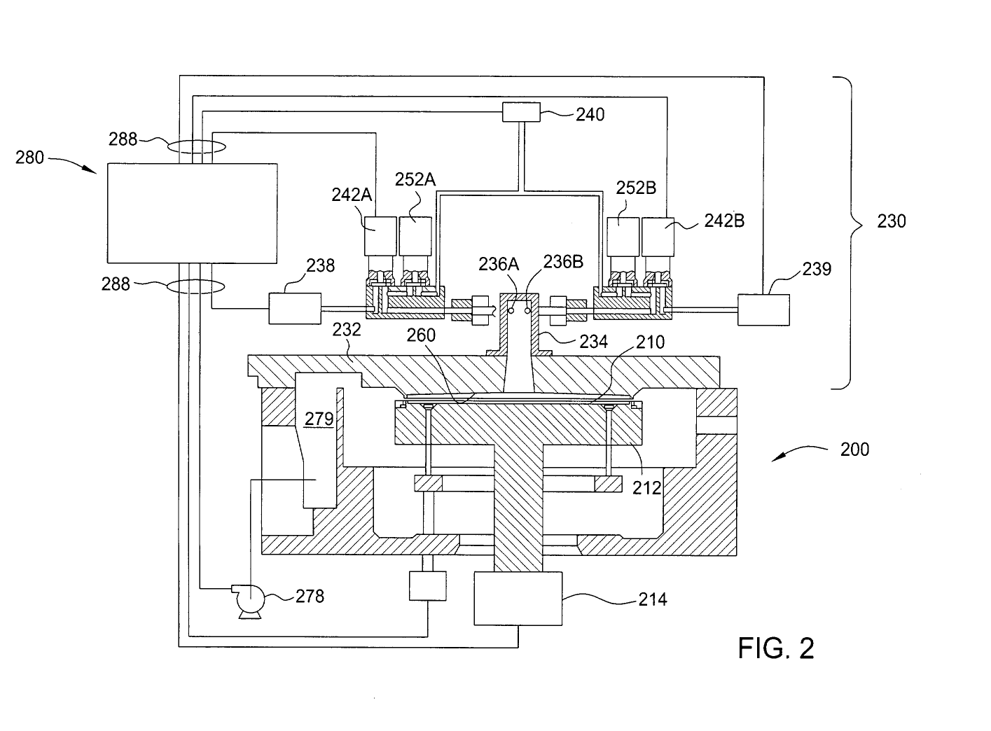

FIG. 2 depicts a schematic cross-sectional view of a process chamber 200 that can be used for the practice of embodiments described herein. The process chamber 200 includes a substrate support 212, which is used to support a substrate 210 within the process chamber 200. The substrate support 212 is moveable in a vertical direction inside the process chamber 200 using a displacement mechanism 214. The substrate support may also include a vacuum chuck (not shown), an electrostatic chuck (not shown), or a clamp ring (not shown) for securing the substrate 210 thereto during a deposition sequence.

Depending on the specific deposition process, the substrate 210 may be heated to some desired temperature prior to or during deposition. For example, the substrate support 212 may be heated using an embedded heater element (not shown). The substrate support 212 may be resistively heated by applying an electric current from an AC power supply (not shown) to the heater element (not shown). The substrate 210 is, in turn, heated by the substrate support 212. Alternatively, the substrate support may be heated using radiant heaters such as, for example, lamps (not shown).

A vacuum pump 278, in communication with a pumping channel 279, is used to evacuate the process chamber 200 and to maintain the pressure inside the process chamber 200. A gas delivery system 230 is disposed on an upper portion of the process chamber 200. The gas delivery system 230 provides process gases to the process chamber 200.

The gas delivery system 230 may comprise a chamber lid 232. The chamber lid 232 includes an expanding channel 234 extending from a central portion of the chamber lid 232 as well as a bottom surface 260 extending from the expanding channel 234 to a peripheral portion of the chamber lid 232. The bottom surface 260 of the chamber lid 232 is sized and shaped to substantially cover the substrate 210 disposed on the substrate support 212. The expanding channel 234 also includes gas inlets 236A, 236B through which gases are provided thereto.

The gas inlets 236A, 236B are coupled to electronic control valves 242A, 242B, 252A, 252B. Electronic control valves 242A, 242B may be coupled to process gas sources 238, 239, respectively, while electronic control valves 252A, 252B may be coupled to a gas source 240. The electronic control valves 242A, 242B, 252A, 252B as used herein refer to any control valve capable of providing rapid and precise gas flow to the process chamber 200 with valve open and close cycles of less than about 1-2 seconds, and more preferably less than about 0.1 second. Proper control and regulation of gas flows to the gas delivery system 230 are performed by a microprocessor controller 280.

The microprocessor controller 280 may be one of any form of general purpose computer processor (CPU) that can be used in an industrial setting for controlling various chambers and sub-processors. The computer may use any suitable memory, such as random access memory, read only memory, floppy disk drive, hard disk, or any other form of digital storage, local or remote. Various support circuits may be coupled to the CPU for supporting the processor in a conventional manner. Software routines as required may be stored in the memory or executed by a second CPU that may be remotely located.

The software routines, when executed, transform the general purpose computer into a specific process computer that controls the chamber operation so that a chamber process is performed. For example, software routines may be used to precisely control the activation of the electronic control valves for the execution of process sequences according to embodiments described herein. Alternatively, the software routines may be performed in hardware, as an application specific integrated circuit or other type of hardware implementation, or a combination of software or hardware.

Copper Layer Formation

A method of forming a copper layer on a substrate is described. The copper layer is formed using a cyclic deposition technique.

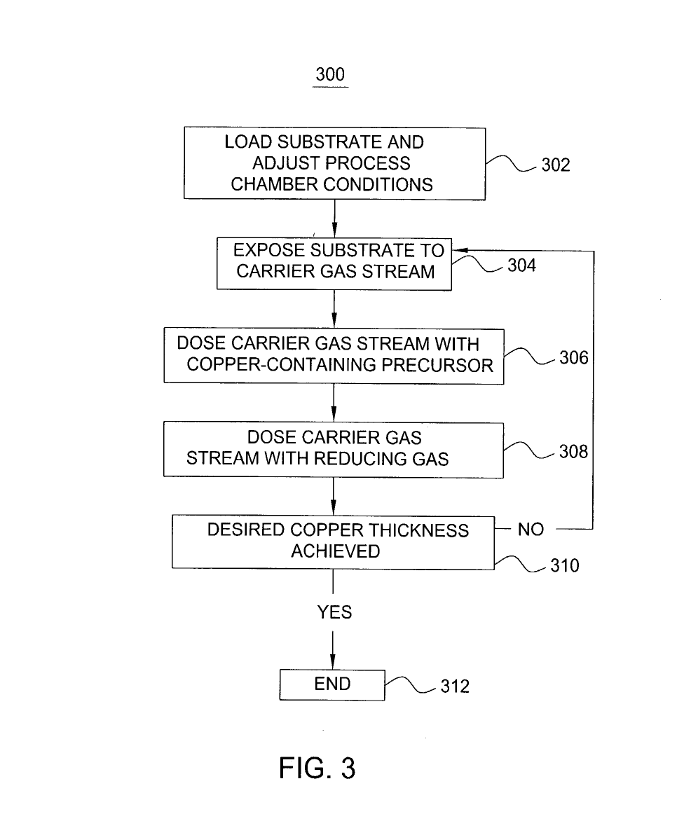

FIG. 3 illustrates an embodiment of a cyclical deposition process sequence 300 according to the present invention detailing the various steps used for the formation of the copper layer utilizing a constant carrier gas flow. These steps may be performed in a process chamber similar to that described above with respect to FIG. 2.

As indicated in step 302, a substrate is provided to a process chamber. The substrate may be for example, a silicon substrate having an interconnect pattern defined in one or more dielectric material layers formed thereon. The process chamber conditions such as, for example, the temperature and pressure are adjusted to enhance the adsorption of the process gases on the substrate. In general, for copper layer deposition, the process chamber should be maintained at a temperature less than about 180° C. and a pressure within a range of about 1 torr to about 10 torr.

In one embodiment where a constant carrier gas flow is desired, a carrier gas stream is established within the process chamber, as indicated in step 304. Carrier gases may be selected so as to also act as a purge gas for the removal of volatile reactants and/or by-products from the process chamber. Carrier gases such as, for example, helium (He) and argon (Ar), and combinations thereof, among others may be used.

Referring to step 306, after the carrier gas stream is established within the process chamber, a pulse of a copper-containing precursor is added to the carrier gas stream. The term pulse as used herein refers to a dose of material added to the carrier gas stream. The pulse of the copper-containing precursor lasts for a predetermined interval.

The time interval for the pulse of the copper-containing precursor is variable depending on a number of factors, such as, for example, the volume capacity of the process chamber employed, the vacuum system coupled thereto and the volatility/reactivity of the reactants used. For example, (1) a large-volume process chamber may lead to a longer time to stabilize the process conditions such as, for example, carrier purge gas flow and temperature, requiring a longer pulse time; (2) a lower flow rate for the process gas may also lead to a longer time to stabilize the process conditions, requiring a longer pulse time; and (3) a lower chamber pressure means that the process gas is evacuated from the process chamber more quickly, requiring a longer pulse time. In general, the process conditions are advantageously selected so that a pulse of the copper-containing precursor provides a sufficient amount of precursor so that at least a monolayer of the copper-containing precursor is adsorbed on the substrate. Thereafter, excess copper-containing precursor remaining in the chamber may be removed from the process chamber by the constant carrier gas stream in combination with the vacuum system.

In step 308, after the excess copper-containing precursor has been removed from the process chamber by the constant carrier gas stream, a pulse of a reducing gas is added to the carrier gas stream. The pulse of the reducing gas also lasts for a predetermined time interval that is variable as described above with reference to the copper-containing precursor. In general, the time interval for the pulse of the reducing gas should be long enough for adsorption of at least a monolayer of the reducing gas on the copper-containing precursor. Thereafter, excess reducing gas remaining in the chamber may be removed therefrom by the constant carrier gas stream in combination with the vacuum system.

Steps 304 through 308 comprise one embodiment of a deposition cycle for copper layer deposition. For such an embodiment, a constant flow of the carrier gas is provided to the process chamber modulated by alternating periods of pulsing and non-pulsing where the periods of pulsing alternate between the copper-containing precursor and the reducing gas along with the carrier gas stream, while the periods of non-pulsing include only the carrier gas stream.

The time interval for each of the pulses of the copper-containing precursor and the reducing gas may have the same duration. That is, the duration of the pulse of the copper-containing precursor may be identical to the duration of the pulse of the reducing gas. For such an embodiment, a time interval (T₁) for the pulse of the copper-containing precursor equals a time interval (T₂) for the pulse of the reducing gas.

Alternatively, the time interval for each of the pulses of the copper-containing precursor and the reducing gas may have different durations. That is, the duration of the pulse of the copper-containing precursor may be shorter or longer than the duration of the pulse of the reducing gas. For such an embodiment, the time interval (T₁) for the pulse of the copper-containing precursor is different than the time interval (T₂) for the pulse of the reducing gas.

In addition, the periods of non-pulsing between each of the pulses of the copper-containing precursor and the reducing gas may have the same duration. That is, the duration of the period of non-pulsing between each pulse of the copper-containing precursor and each pulse of the reducing gas may be identical. For such an embodiment, a time interval (T₃) of non-pulsing between the pulse of the copper-containing precursor and the pulse of the reducing gas equals a time interval (T₄) of non-pulsing between the pulse of the reducing gas and the pulse of the copper-containing precursor. During the time periods of non-pulsing only the constant carrier gas stream is provided to the process chamber.

Alternatively, the periods of non-pulsing between each of the pulses of the copper-containing precursor and the reducing gas may have different durations. That is, the duration of the period of non-pulsing between each pulse of the copper-containing precursor and each pulse of the reducing gas may be shorter or longer than the duration of the period of non-pulsing between each pulse of the reducing gas and the pulse of the copper-containing precursor. For such an embodiment, a time interval (T₃) of non-pulsing between the pulse of the copper-containing precursor and the pulse of the reducing gas is different from a time interval (T₄) of non-pulsing between the pulse of the reducing gas and the pulse of the copper-containing precursor. During the time periods of non-pulsing only the constant carrier gas stream is provided to the process chamber.

Additionally, the time intervals for each pulse of the copper-containing precursor, the reducing gas and the periods of non-pulsing therebetween for each deposition cycle may have the same duration. For such an embodiment, a time interval (T₁) for the pulse of the copper-containing precursor, a time interval (T₂) for the pulse of the reducing gas, a time interval (T₃) of non-pulsing between the pulse of the copper-containing precursor and the pulse of the reducing gas and a time interval (T₄) of non-pulsing between the pulse of the reducing gas and the pulse of the copper-containing precursor each have the same value for each deposition cycle. For example, in a first deposition cycle (C₁), a time interval (T₁) for the pulse of the copper-containing precursor has the same duration as the time interval (T₁) for the pulse of the copper-containing precursor in subsequent deposition cycles (C₂ . . . C_{N}). Similarly, the duration of each pulse of the reducing gas as well as the periods of non-pulsing between the pulse of the copper-containing precursor and the reducing gas in the first deposition cycle (C₁) is the same as the duration of each pulse of the reducing gas and the periods of non-pulsing between the pulse of the copper-containing precursor and the reducing gas in subsequent deposition cycles (C₂ . . . C_{N}), respectively.

Alternatively, the time intervals for at least one pulse of the copper-containing precursor, the reducing gas and the periods of non-pulsing therebetween for one or more of the deposition cycles of the copper layer may have different durations. For such an embodiment, one or more of the time intervals (T₁) for the copper-containing precursor, the time intervals (T₂) for the reducing gas, the time intervals (T₃) of non-pulsing between the pulse of the copper-containing precursor and the pulse of the reducing gas and the time intervals (T₄) of non-pulsing between the pulse of the reducing gas and the pulse of the copper-containing precursor may have different values for one or more deposition cycles of the cyclical deposition process. For example, in a first deposition cycle (C₁), the time interval (T₁) for the pulse of the copper-containing precursor may be longer or shorter than the time interval (T₁) for the pulse of the copper-containing precursor in subsequent deposition cycles (C₂ . . . C_{N}). Similarly, the duration of each pulse of the reducing gas and the periods of non-pulsing between the pulse of the copper-containing precursor and the reducing gas in the first deposition cycle (C₁) may be the same or different than the duration of corresponding pulses of the reducing gas and periods of non-pulsing between the pulse of the copper-containing precursor and the reducing gas in subsequent deposition cycles (C₂ . . . C_{N}), respectively.

Referring to step 310, after each deposition cycle (steps 304 through 308) a thickness of the copper will be formed on the substrate. Depending on specific device requirements, subsequent deposition cycles may be needed to achieve a desired thickness. As such, steps 304 through 308 are repeated until the desired thickness for the copper layer is achieved. Thereafter, when the desired thickness for the copper layer is achieved the process is stopped as indicated by step 212.

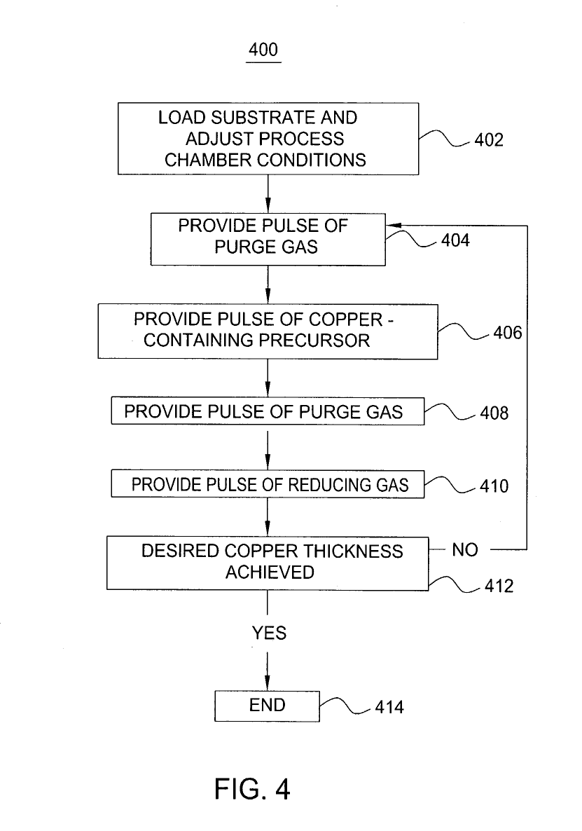

In an alternate process sequence described with respect to FIG. 4, the copper layer deposition cycle comprises separate pulses for each of the copper-containing precursor, the reducing gas and a purge gas. For such an embodiment, a copper layer deposition sequence 400 includes providing a substrate to the process chamber and adjusting the process chamber conditions (step 402), providing a first pulse of a purge gas to the process chamber (step 404), providing a pulse of a copper-containing precursor to the process chamber (step 406), providing a second pulse of a purge gas to the process chamber (step 408), providing a pulse of a reducing gas to the process chamber (step 410), and then repeating steps 404 through 410, or stopping the deposition process (step 414) depending on whether a desired thickness for the copper layer has been achieved (step 412).

The time intervals for each of the pulses of the copper-containing precursor, the reducing gas and the purge gas may have the same or different durations as discussed above with respect to FIG. 3. Alternatively, corresponding time intervals for one or more pulses of the copper-containing precursor, the reducing gas and the purge gas in one or more of the deposition cycles of the copper layer deposition process may have different durations.

In FIGS. 3-4, the copper layer deposition cycle is depicted as beginning with a pulse of the copper-containing precursor followed by a pulse of the reducing gas. Alternatively, the copper layer deposition cycle may start with a pulse of the reducing gas followed by a pulse of the copper-containing precursor.

The copper-containing precursor may comprise an organometallic copper complex such as, for example, copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂, among others. Suitable reducing gases may include for example, silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), among others.

One exemplary process of depositing a copper layer comprises sequentially providing pulses of copper⁺¹ hexafluoroacetylacetonate trimethylvinylsilane (Cu⁺¹(hfac)(TMVS)) and pulses of diborane (B₂H₆). The copper⁺¹ hexafluoroacetylacetonate trimethylvinylsilane (Cu⁺¹(hfac)(TMVS) may be provided to an appropriate flow control valve, for example, an electronic control valve, at a flow rate of between about 0.01 sccm (standard cubic centimeters per minute) and about 5 sccm, preferably between about 0.1 sccm and about 1 sccm, and thereafter pulsed for about 5 seconds or less, preferably about 1 second or less. The diborane (B₂H₆) may be provided to an appropriate flow control valve, for example, an electronic flow control valve, at a flow rate of between about 1 sccm to about 80 sccm, preferably between about 10 sccm and about 50 sccm, and thereafter pulsed for about 10 seconds or less, preferably about 2 seconds or less. The substrate may be maintained at a temperature less than about 180° C., preferably about 120° C. at a chamber pressure between about 0.1 torr to about 10 torr, preferably about 1 torr.

Another exemplary process of depositing a copper layer comprises sequentially providing pulses of copper⁺¹ hexafluoroacetylacetonate trimethylvinylsilane (Cu⁺¹(hfac)(TMVS)) and pulses of silane (SiH₄). The copper⁺¹ hexafluoroacetylacetonate trimethylvinylsilane (Cu⁺¹(hfac)(TMVS) may be provided to an appropriate flow control valve, for example, an electronic control valve, at a flow rate of between about 0.1 sccm (standard cubic centimeters per minute) and about 5 sccm, preferably between about 0.1 sccm and about 1 sccm, and thereafter pulsed for about 5 seconds or less, preferably about 1 second or less. The silane (SiH₄) may be provided to an appropriate flow control valve, for example, an electronic flow control valve, at a flow rate of between about 1 sccm to about 100 sccm, preferably between about 10 sccm and about 50 sccm, and thereafter pulsed for about 10 seconds or less, preferably about 2 seconds or less. The substrate may be maintained at a temperature less than about 180° C., preferably about 120° C. at a chamber pressure between about 0.1 torr to about 10 torr, preferably about 1 torr.

Formation of Copper Interconnects

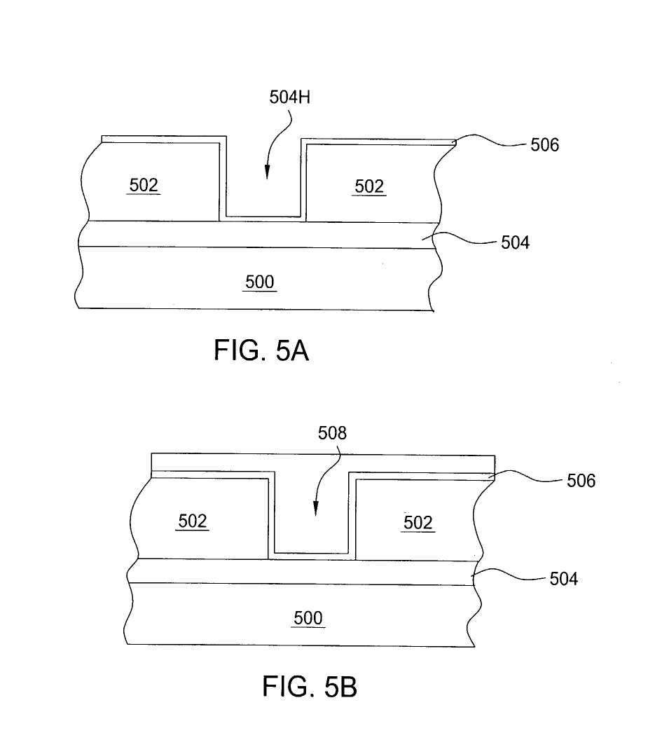

FIGS. 5A-5B illustrate cross-sectional views of a substrate at different stages of a copper interconnect fabrication sequence incorporating the copper layer of the present invention. FIG. 5A, for example, illustrates a cross-sectional view of a substrate 500 having metal contacts 504 and a dielectric layer 502 formed thereon. The substrate 500 may comprise a semiconductor material such as, for example, silicon (Si), germanium (Ge), or gallium arsenide (GaAs). The dielectric layer 502 may comprise an insulating material such as, for example, silicon oxide or silicon nitride, among others. The metal contacts 504 may comprise for example, copper (Cu), among others. Apertures 504H may be defined in the dielectric layer 502 to provide openings over the metal contacts 504. The apertures 504H may be defined in the dielectric layer 502 using conventional lithography and etching techniques.

A barrier layer 506 may be formed in the apertures 504H defined in the dielectric layer 502. The barrier layer 506 may include one of more refractory metal-containing layers such as, for example, titanium (Ti), titanium nitride (TiN), tantalum (Ta), tantalum nitride (TaN), tungsten (W), tungsten nitride (WN), tantalum silicide nitride and titanium silicide nitride, among others. The barrier layer 506 may be formed using a suitable deposition process. For example, titanium nitride (TiN) may be deposited with a chemical vapor deposition (CVD) process from a reaction of titanium tetrachloride (TiCl₄) and ammonia (NH₃). Titanium silicide nitride (TiSiN) may be deposited by forming a titanium nitride (TiN) layer via thermal decomposition of tetrakis(dimethylamido) titanium (TDMAT) followed by exposure to silane (SiH₄).

Thereafter, referring to FIG. 5B, the apertures 504H may be filled with copper (Cu) metallization to complete the copper interconnect. The copper metallization is formed using the cyclical deposition techniques described above with respect to FIGS. 3-4.

While foregoing is directed to the preferred embodiment of the present invention, other and further embodiments of the invention may be devised without departing from the basic scope thereof, and the scope thereof is determined by the claims that follow.

What is claimed is:

1. A method of forming a copper layer on a substrate, comprising:
(a) providing a substrate to a process chamber; and
(b) forming a copper layer on the substrate using a cyclical deposition process, wherein the cyclical deposition process includes a plurality of cycles and wherein each cycle comprises establishing a flow of an inert gas in the process chamber and modulating the flow of the inert gas with alternating periods of exposure to one of a copper-containing precursor and a reducing gas.

2. The method of claim 1 wherein the period of exposure to the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor each have the same duration.

3. The method of claim 1 wherein at least one of the period of exposure the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor has a different duration.

4. The method of claim 1 wherein the period of exposure to the copper-containing precursor during each deposition cycle of the cyclical deposition process has the same duration.

5. The method of claim 1 wherein at least one period of exposure to the copper-containing precursor for one or more deposition cycle of the cyclical deposition process has a different duration.

6. The method of claim 1 wherein the period of exposure to the reducing gas during each deposition cycle of the cyclical deposition process has the same duration.

7. The method of claim 1 wherein at least one period of exposure to the reducing gas for one or more deposition cycle of the cyclical deposition process has a different duration.

8. The method of claim 1 wherein a period of flow of the inert gas between the period of exposure to the copper-containing precursor and the reducing gas during each deposition cycle of the cyclical-deposition process has the same duration.

9. The method of claim 1 wherein at least one period of flow of the inert gas between the period of exposure to the copper-containing precursor and the reducing gas during each deposition cycle of the cyclical deposition process has a different duration.

10. The method of claim 1 wherein a period of flow of the inert gas between the period of exposure to the reducing gas and the copper-containing precursor during each deposition cycle of the cyclical deposition process has the same duration.

11. The method of claim 1 wherein at least one period of flow of the inert gas between the period of exposure to the reducing gas and the copper-containing precursor for one or more deposition cycles of the cyclical deposition process has a different duration.

12. The method of claim 1 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

13. The method of claim 1 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

14. The method of claim 1 wherein the process chamber is maintained at a temperature less than about 180° C.

15. A method of forming a copper layer on a substrate, comprising:
(a) providing a substrate to a process chamber; and
(b) forming a copper layer on the substrate using a cyclical deposition process, wherein the cyclical deposition process includes a plurality of cycles, wherein each cycle comprises establishing a flow of an inert gas in the process chamber and modulating the flow of the inert gas with alternating periods of exposure to one of a copper-containing precursor and a reducing gas, wherein the period of exposure to the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor each have the same duration.

16. The method of claim 15 wherein the period of exposure to the copper-containing precursor during each deposition cycle of the cyclical deposition process has the same duration.

17. The method of claim 15 wherein at least one period of exposure to the copper-containing precursor for one or more deposition cycle of the cyclical deposition process has a different duration.

18. The method of claim 15 wherein the period of exposure to the reducing gas during each deposition cycle of the cyclical deposition process has the same duration.

19. The method of claim 15 wherein at least one period of exposure to the reducing gas for one or more deposition cycle of the cyclical deposition process has a different duration.

20. The method of claim 15 wherein a period of flow of the inert gas between the period of exposure to the copper-containing precursor and the reducing gas during each deposition cycle of the cyclical deposition process has the same duration.

21. The method of claim 15 wherein at least one period of flow of the inert gas between the period of exposure to the copper-containing precursor and the reducing gas during each deposition cycle of the cyclical deposition process has a different duration.

22. The method of claim 15 wherein a period of flow of the inert gas between the period of exposure to the reducing gas and the copper-containing precursor during each deposition cycle of the cyclical deposition process has the same duration.

23. The method of claim 15 wherein at least one period of flow of the inert gas between the period of exposure to the reducing gas and the copper-containing precursor for one or more deposition cycles of the cyclical deposition process has a different duration.

24. The method of claim 15 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

25. The method of claim 15 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

26. The method of claim 15 wherein the process chamber is maintained at a temperature less than about 180° C.

27. A method of forming a copper layer on a substrate, comprising:
(a) providing a substrate to a process chamber; and
(b) forming a copper layer on the substrate using a cyclical deposition process, wherein the cyclical deposition process includes a plurality of cycles, wherein each cycle comprises establishing a flow of an inert gas in the process chamber and modulating the flow of the inert gas with alternating periods of exposure to one of a copper-containing precursor and a reducing gas, and wherein at least one of the period of exposure the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor has a different duration.

28. The method of claim 27 wherein the period of exposure to the copper-containing precursor during each deposition cycle of the cyclical deposition process has the same duration.

29. The method of claim 27 wherein at least one period of exposure to the copper-containing precursor for one or more deposition cycle of the cyclical deposition process has a different duration.

30. The method of claim 27 wherein the period of exposure to the reducing gas during each deposition cycle of the cyclical deposition process has the same duration.

31. The method of claim 27 wherein at least one period of exposure to the reducing gas for one or more deposition cycle of the cyclical deposition process has a different duration.

32. The method of claim 27 wherein a period of flow of the inert gas between the period of exposure to the copper-containing precursor and the reducing gas during each deposition cycle of the cyclical deposition process has the same duration.

33. The method of claim 27 wherein at least one period of flow of the inert gas between the period of exposure to the copper-containing precursor and the reducing gas during each deposition cycle of the cyclical deposition process has a different duration.

34. The method of claim 27 wherein a period of flow of the inert gas between the period of exposure to the reducing gas and the copper-containing precursor during each deposition cycle of the cyclical deposition process has the same duration.

35. The method of claim 27 wherein at least one period of flow of the inert gas between the period of exposure to the reducing gas and the copper-containing precursor for one or more deposition cycles of the cyclical deposition process has a different duration.

36. The method of claim 27 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

37. The method of claim 27 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

38. The method of claim 27 wherein the process chamber is maintained at a temperature less than about 180° C.

39. A method of forming a copper layer on a substrate, comprising:
(a) providing a substrate to a process chamber; and
(b) forming a copper layer on the substrate using a cyclical deposition process, wherein the cyclical deposition process includes a plurality of cycles, wherein each cycle comprises establishing a flow of an inert gas in the process chamber and modulating the flow of the inert gas with alternating periods of exposure to one of a copper-containing precursor and a reducing gas, wherein the period of exposure to the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor each have the same duration and wherein the period of exposure to the reducing gas, the period of flow of the inert gas between the period of exposure to the copper-containing precursor and the period of exposure to the reducing gas, and the period of flow of the inert gas between the period of exposure to the reducing gas and the period of exposure to the copper-containing precursor each have the same duration during each deposition cycle of the cyclical deposition process.

40. The method of claim 39 wherein the copper-containing precursor comprises a material selected from the group consisting of copper diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

41. The method of claim 39 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

42. The method of claim 39 wherein the process chamber is maintained at a temperature less than about 180° C.

43. A method of forming a copper layer on a substrate, comprising:
(a) providing a substrate to a process chamber; and
(b) forming a copper layer on the substrate using a cyclical deposition process, wherein the cyclical deposition process includes a plurality of cycles, wherein each cycle comprises establishing a flow of an inert gas in the process chamber and modulating the flow of the inert gas with alternating periods of exposure to one of a copper-containing precursor and a reducing gas, wherein the period of exposure to the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor each have the same duration and wherein at least one period of exposure to the reducing gas, the period of flow of the inert gas between the period of exposure to the copper-containing precursor and the period of exposure to the reducing gas, and the period of flow of the inert gas between the period of exposure to the reducing gas and the period of exposure to the copper-containing precursor has a different duration during one or more deposition cycles of the cyclical deposition process.

44. The method of claim 43 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

45. The method of claim 43 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

46. The method of claim 43 wherein the process chamber is maintained at a temperature less than about 180° C.

47. A method of forming a copper layer on a substrate, comprising:
(a) providing a substrate to a process chamber; and
(b) forming a copper layer on the substrate using a cyclical deposition process, wherein the cyclical deposition process includes a plurality of cycles, wherein each cycle comprises establishing a flow of an inert gas in the process chamber and modulating the flow of the inert gas with alternating periods of exposure to one of a copper-containing precursor and a reducing gas, wherein at least one of the period of exposure the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor has a different duration, and the period of flow of the inert gas between the period of exposure to the reducing gas and the period of exposure to the copper-containing precursor each have the same duration during each deposition cycle of the cyclical deposition process.

48. The method of claim 47 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

49. The method of claim 47 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

50. The method of claim 47 wherein the process chamber is maintained at a temperature less than about 180° C.

51. A method of forming a copper layer on a substrate, comprising:
(a) providing a substrate to a process chamber; and
(b) forming a copper layer on the substrate using a cyclical deposition process, wherein the cyclical deposition process includes a plurality of cycles, wherein each cycle comprises establishing a flow of an inert gas in the process chamber and modulating the flow of the inert gas with alternating periods of exposure to one of a copper-containing precursor and a reducing gas, wherein at least one of the period of exposure the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor has a different duration, and wherein at least one period of exposure to the reducing gas, the period of flow of the inert gas between the period of exposure to the copper-containing precursor and the period of exposure to the reducing gas, and the period of flow of the inert gas between the period of exposure to the reducing gas and the period of exposure to the copper-containing precursor has a different duration during one or more deposition cycles of the cyclical deposition process.

52. The method of claim 51 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺²hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

53. The method of claim 51 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

54. The method of claim 51 wherein the process chamber is maintained at a temperature less than about 180° C.

55. A method of forming an interconnect structure, comprising:
(a) providing a substrate structure to a process chamber, wherein the substrate structure includes an insulating material layer having vias defined therethrough to an electrode; and
(b) forming a copper layer on the electrode using a cyclical deposition process, wherein the cyclical deposition process includes a plurality of cycles and wherein each cycle comprises establishing a flow of an inert gas in the process chamber and modulating the flow of the inert gas with alternating periods of exposure to one of a copper-containing precursor and a reducing gas.

56. The method of claim 55 wherein the period of exposure to the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor each have the same duration.

57. The method of claim 55 wherein at least one of the period of exposure the copper-containing precursor, the period of exposure to the reducing gas, a period of flow of the inert gas between the period of exposure to the copper-containing precursor and the period of exposure to the reducing gas, and a period of flow of the inert gas between the period of exposure to the reducing gas and the period of exposure to the copper-containing precursor has a different duration.

58. The method of claim 55 wherein the period of exposure to the copper-containing precursor during each deposition cycle of the cyclical deposition process has the same duration.

59. The method of claim 55 wherein at least one period of exposure to the copper-containing precursor for one or more deposition cycle of the cyclical deposition process has a different duration.

60. The method of claim 55 wherein the period of exposure to the reducing gas during each deposition cycle of the cyclical deposition process has the same duration.

61. The method of claim 55 wherein at least one period of exposure to the reducing gas for one or more deposition cycle of the cyclical deposition process has a different duration.

62. The method of claim 55 wherein a period of flow of the inert gas between the period of exposure to the copper-containing precursor and the reducing gas during each deposition cycle of the cyclical deposition process has the same duration.

63. The method of claim 55 wherein at least one period of flow of the inert gas between the period of exposure to the copper-containing precursor and the reducing gas during each deposition cycle of the cyclical deposition process has a different duration.

64. The method of claim 55 wherein a period of flow of the inert gas between the period of exposure-to the reducing gas and the copper-containing precursor during each deposition cycle of the cyclical deposition process has the same duration.

65. The method of claim 55 wherein at least one period of flow of the inert gas between the period of exposure to the reducing gas and the copper-containing precursor for one or more deposition cycles of the cyclical deposition process has a different duration.

66. The method of claim 55 wherein the copper-containing precursor comprises a material selected from the group consisting of copper⁺¹ (β-diketonate)silylolefin complexes including copper⁺¹ hexafluoroacetylacetonate trimethylvinylsilane (Cu⁺¹(hfac)(TMVS)), copper⁺² hexafluoroacetylacetonate (Cu⁺²(hfac)₂), copper⁺² diacetylacetonate (Cu⁺²(acac)₂) and 2Cu Me₂NsiMe₂CH₂CH₂SiNMe₂.

67. The method of claim 55 wherein the reducing gas comprises one or more gases selected from the group consisting of silane (SiH₄), disilane (Si₂H₆), dimethylsilane (SiC₂H₈), methyl silane (SiCH₆), ethylsilane (SiC₂H₈), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

68. The method of claim 55 wherein the process chamber is maintained at a temperature less than about 180° C.
